(19) United States
(12) Patent Application Publication
(10) Pub. No.: US 2017/0187338 A1
(43) Pub. Date: Jun. 29, 2017

(54) AMPLIFIER WITH COUPLED INDUCTORS

(71) Applicant: QUALCOMM Incorporated, San Diego, CA (US)

(72) Inventors: Chuan Wang, San Diego, CA (US); Kevin Hsi Huai Wang, San Diego, CA (US); Xinhua Chen, San Diego, CA (US); Mehmet Uzunkol, San Diego, CA (US)

(21) Appl. No.: 15/188,629

(22) Filed: Jun. 21, 2016

Related U.S. Application Data
(60) Provisional application No. 62/387,344, filed on Dec. 23, 2015.

(51) Int. Cl. H03F 1/56; H03F 3/195; H03F 3/193

(52) U.S. Cl. CPC H03F 1/565; H03F 3/193; H03F 3/195; H03F 2200/451; H03F 2200/294

(57) ABSTRACT

An apparatus includes an inductor device including a first inductor coupled to a second inductor. The first inductor and the second inductor are connected to ground. A first transistor and a second transistor are coupled to the inductor device. A first cascode transistor is coupled to the first transistor, and a second cascode transistor is coupled to the second transistor. The first cascode transistor is coupled to a first output, and the second cascode transistor is coupled to a second output.

### I. CROSS REFERENCE TO RELATED APPLICATIONS

The present application claims the benefit of U.S. Provisional Patent Application No. 62/387,344, entitled “AMPLIFIER WITH COUPLED INDUCTORS,” filed Dec. 23, 2015, which is expressly incorporated by reference herein in its entirety.

### II. FIELD

The present disclosure is generally related to electronics, and more specifically to amplifiers that may be used in wireless communication devices.

### III. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities and may support increasing wireless communication capability, particularly in downlink communications that provide information to the wireless telephones.

Wireless telephones may use radio frequency (RF) components to transmit and to receive wireless signals. For example, carrier aggregation (CA) signals are radiofrequency (RF) signals that include two or more component carriers. Intra-band CA includes multiple component carriers within a single frequency band. Receivers that support intra-band CA may include a low noise amplifier (LNA) that receives a single input signal and generates multiple outputs (e.g., an output for each of the multiple component carriers). However, LNAs that are configurable to support multiple-output operation and that include a separate degeneration inductor for each of the multiple outputs use more area and have degraded noise figures as compared to a single-output LNA.

### IV. BRIEF DESCRIPTION OF THE DRAWINGS

FIG. 1 shows a wireless device that includes a multi-output amplifier with negatively coupled degeneration inductors, the wireless device communicating with a wireless system.

FIG. 2 is a block diagram that illustrates components of the wireless device in FIG. 1.

FIG. 3 is a block diagram of an exemplary embodiment of components including an amplifier that may be included in the wireless device of FIG. 1.

FIG. 4 is a block diagram of another exemplary embodiment of components including an amplifier that may be included in the wireless device of FIG. 1.

FIG. 5 is a block diagram of another exemplary embodiment of components including an amplifier that may be included in the wireless device of FIG. 1.

FIG. 6A is a graphical diagram showing an example of contiguous intra-band carrier-aggregation (CA) that may be used by the wireless device of FIG. 1.

FIG. 6B is a graphical diagram showing an example of non-contiguous intra-band CA that may be used by the wireless device of FIG. 1.

FIG. 6C is a graphical diagram showing an example of inter-band CA in the same band group that may be used by the wireless device of FIG. 1.

FIG. 6D is a graphical diagram showing an example of inter-band CA in different band groups that may be used by the wireless device of FIG. 1.

FIG. 7 is a diagram showing an example of an inductor device that may be included in the wireless device of FIG. 1.

FIG. 8 illustrates a flowchart of a method that may be performed by the wireless device of FIG. 1.

### V. DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. As used herein, “coupled,” along with its derivatives, may mean one or more of the following. “Coupled” may mean a direct physical or electrical coupling or connection, where there is no other element coupled or connected between the elements that are said to be coupled with each other. “Coupled” may also mean an indirect physical or electrical coupling or connection, where one or more other elements are coupled or connected between the elements that are said to be coupled with each other. “Connected” may mean a direct physical or electrical coupling, where there is no other element coupled or connected between the elements that are said to be connected to each other.

Further, it is to be appreciated that certain ordinal terms (e.g., “first” or “second”) may be provided for ease of reference and do not necessarily imply physical characteristics or ordering. Therefore, as used herein, an ordinal term (e.g., “first,” “second,” “third,” etc.) used to modify an element, such as a structure, a component, an operation, etc., does not necessarily indicate priority or order of the element with respect to another element, but rather distinguishes the element from another element having a same name (but for use of the ordinal term). In addition, as used herein, indefinite articles (“a” and “an”) may indicate “one or more” rather than “one.” The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

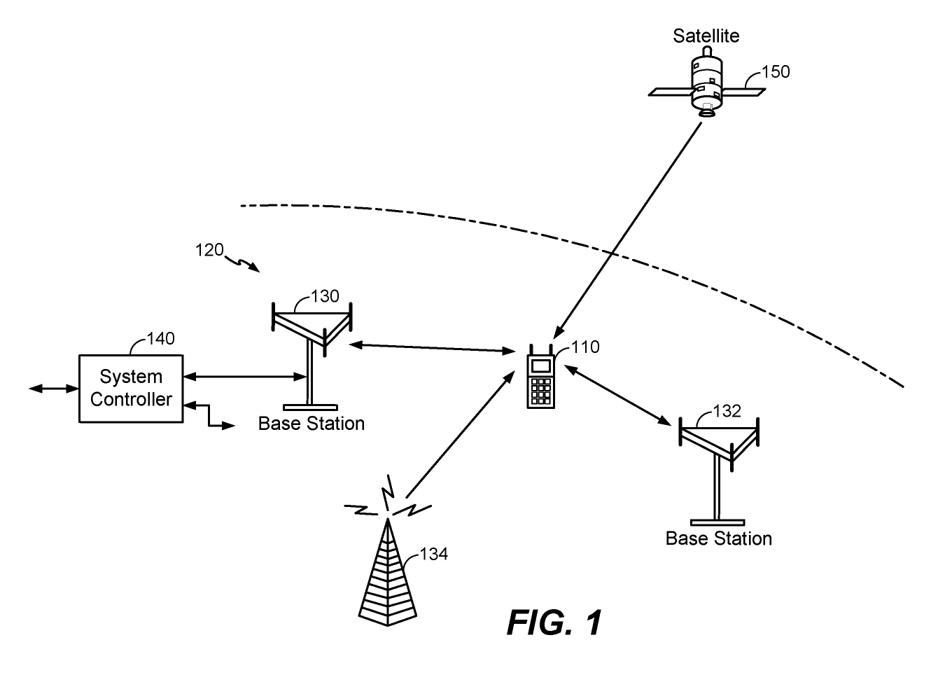

FIG. 1 shows a wireless device 110 communicating with a wireless communication system 120. Wireless communication system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless system may include any number of base stations and any set of network entities.

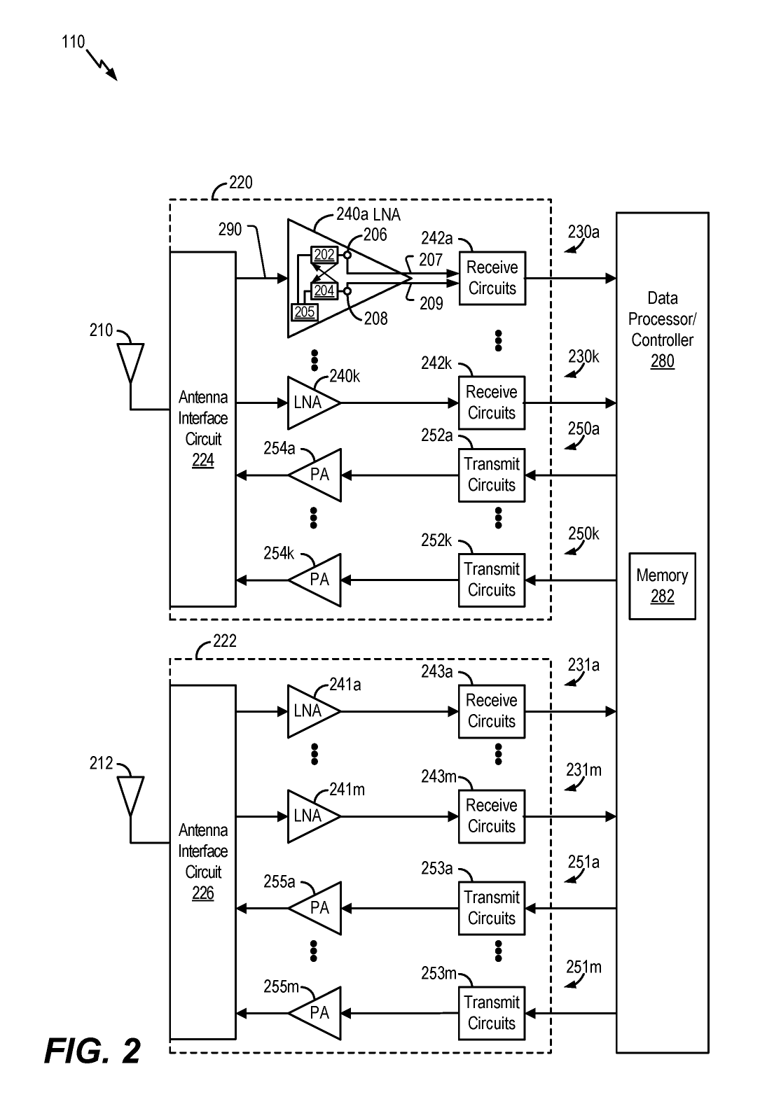

Wireless device 110 may also be referred to as user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth® device (Bluetooth® is a registered trademark of Bluetooth SIG, Inc.), etc. Wireless device 110 may communicate with wireless system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication, such as LTE, WCDMA, CDMA 1×, EVDO, TD-SCDMA, GSM, 802.11, etc. Further, in an exemplary embodiment, the wireless device 110 includes an amplifier, such as an LNA, that includes a degeneration inductor device that has a first inductor coupled to a second inductor. The amplifier may have a single input and multiple single-ended outputs and may be configurable to switch between operating in a single-input single-output (SISO) mode and in a single-input multiple-output (SIMO) mode. A negative coupling coefficient between the first inductor and the second inductor may improve the noise figure of the amplifier and may enable the amplifier to have a smaller area as compared to a SIMO amplifier having multiple uncoupled degeneration inductors. Examples of the amplifier are described in further detail with respect to FIGS. 2-5. Although example embodiments described herein include single-ended inputs and outputs, it should be understood that concepts described herein are not limited to single-ended inputs and outputs and may be applied to differential inputs and differential outputs.

FIG. 2 shows a block diagram of an exemplary design of the wireless device 110 in FIG. 1. In this exemplary design, wireless device 110 includes a transceiver 220 coupled to a primary antenna 210 via an antenna interface circuit 224, a transceiver 222 coupled to a secondary antenna 212 via an antenna interface circuit 226, and a data processor/controller 280. Transceiver 220 includes multiple (K) receivers 230a to 230k and multiple (K) transmitters 250a to 250k to support multiple frequency bands, multiple radio technologies, carrier aggregation, etc. Transceiver 222 includes multiple (M) receivers 231a to 231m and multiple (M) transmitters 251a to 251m to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230a to 230k and 231a to 231m includes one of the LNAs 240a to 240k or 241a to 241m that is configured to provide an RF signal to one of the receive circuits 242a to 242k or 243a to 243m. For data reception, the primary antenna 210 receives signals from base stations and/or other transmitter stations and provides a received RF signal, which is routed through the antenna interface circuit 224. Antenna interface circuit 224 may include switches, duplexers, transmit filters, receive filters, matching circuits, etc. An output of the antenna interface circuit 224 is presented as an input RF signal to one or more of the receivers 230a to 230k, such as via a first input signal path to receiver 230a or via a second input signal path to receiver 230k. Within the one or more of the receivers 230a to 230k, the input RF signal is amplified and provided to the respective one or more receive circuits 242a to 242k.

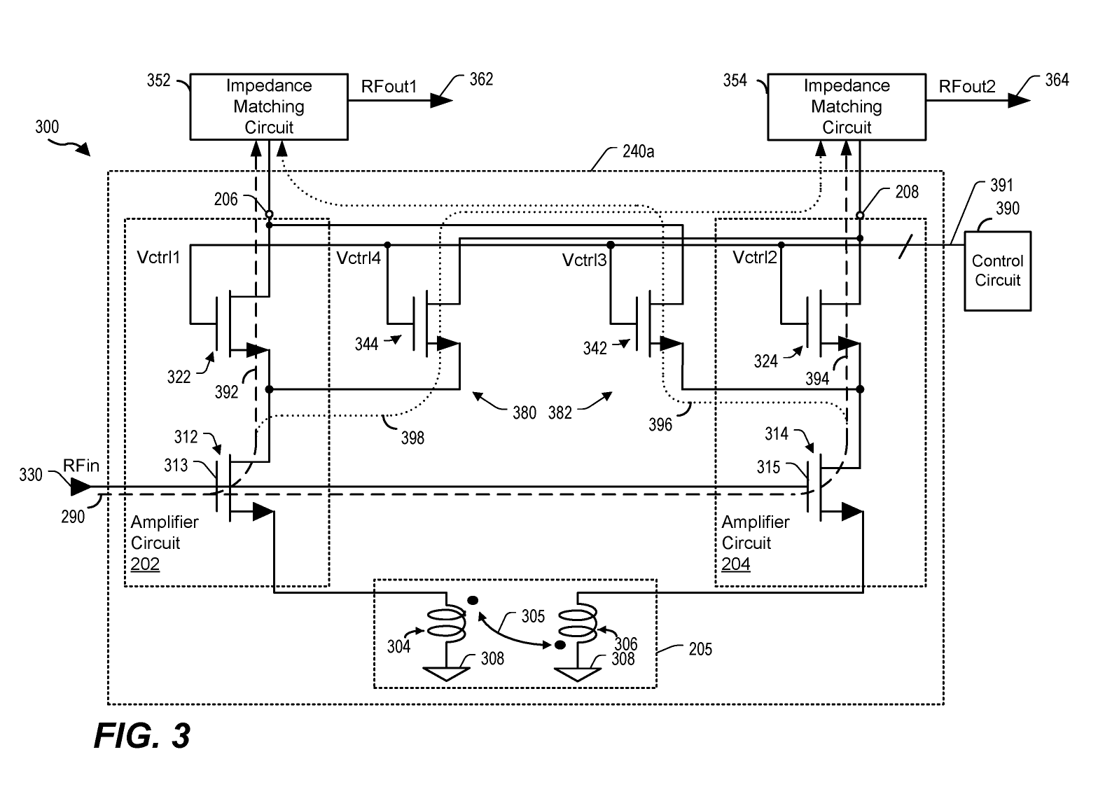

LNA 240a includes a first amplifier circuit 202 and a second amplifier circuit 204 that are coupled to an inductor device 205. The first amplifier circuit 202 is coupled to a first output 206 (e.g., a first single-ended output) and the second amplifier circuit 204 is coupled to a second output 208 (e.g., a second single-ended output). As described in further detail with respect to FIGS. 3-6, the inductor device 205 includes a first inductor coupled to a second inductor, such as via a negative mutual inductance between the first inductor and the second inductor. One or more cascode transistors may be coupled between the first amplifier circuit 202 and the second amplifier circuit 204. In an example configuration (e.g., a SISO configuration) the one or more cascode transistors may be activated to combine an amplified signal from the first amplifier circuit 202 and an amplified signal from the second amplifier circuit 204 at the first output 206. In another example configuration (e.g., another SISO configuration), the one or more cascode transistors may be activated to combine an amplified signal from the first amplifier circuit 202 and an amplified signal from the second amplifier circuit 204 at the second output 208. The one or more cascode transistors coupled between the first amplifier circuit 202 and the second amplifier circuit 204 may be deactivated in a SIMO mode so that a first amplified signal from the first amplifier circuit 202 is output at the first output 206 and a second output signal from the second amplifier circuit 204 is output at the second output 208 in a SIMO mode. As described further with respect to FIG. 3, the coupled inductors in the inductor device 205 may boost transconductance in the SIMO mode and may reduce noise figure due to noise cancellation.

The description below assumes that receiver 230a is selected to receive an RF signal. The RF signal is received from the antenna 210 via the antenna interface circuit 224 and is provided to the LNA 240a as RF signal 290. The LNA 240a generates an amplified RF signal at the first output 206 or the second output 208 (in a SISO mode) or generates a first amplified RF signal at the first output 206 and a second amplified RF signal at the second output 208 (in a SIMO mode). The first output 206 may be coupled to receive circuits 242a (e.g., via one or more switching or routing components) to provide a signal propagation path 207 from the first output 206 to the receive circuits 242a. The second output 208 may be coupled to receive circuits 242a (e.g., via one or more switching or routing components) to provide a signal propagation path 209 from the second output 208 to the receive circuits 242a. Receive circuits 242a downconvert the amplified RF signal(s), amplify and filter the downconverted signal(s), and provide an analog input signal(s) to data processor/controller 280. Receive circuits 242a may include mixers, filters, amplifiers, matching circuits, one or more oscillators, one or more local oscillator (LO) generators, one or more phase locked loop (PLL), etc. Each of the LNAs 240a to 240k and 241a to 241m may include multiple amplifier circuits and an inductor device such as described with respect to the first amplifier circuit 202, the second amplifier circuit 204, and the inductor device 205, and may be configured to operate in a similar manner as described for the LNA 240a.

In the exemplary design shown in FIG. 2, each of the transmitters 250a to 250k and 251a to 251m includes one of the transmit circuits 252a to 252k and 253a to 253m and one of the power amplifiers (PAs) 254a to 254k and 255a to 255m. For data transmission, data processor/controller 280 processes (e.g., encodes and modulates) data to be transmitted and provides an analog output signal to a selected transmitter. The description below assumes that transmitter 250a is the selected transmitter to transmit a RF signal. Within transmitter 250a, transmit circuits 252a amplify, filter, and upconvert the analog output signal from baseband to RF and provide a modulated RF signal. Transmit circuits 252a may include amplifiers, filters, mixers, matching circuits, an oscillator, an LO generator, a PLL, etc. A PA 254a receives and amplifies the modulated RF signal and provides a transmit RF signal having the proper output power level. The transmit RF signal is routed through antenna interface circuit 224 and transmitted via antenna 210. Each of the transmitters 250a to 250k and 251a to 251m in transceivers 220 and 222 may operate in a similar manner as transmitter 250a.

FIG. 2 shows an exemplary design of receivers 230a to 230k and 231a to 231m and transmitters 250a to 250k and 251a to 251m. A receiver and a transmitter may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240a to 240k and 241a to 241m and receive circuits 242a to 242k and 243a to 243m may be implemented on one module, which may be an RFIC, etc.

Data processor/controller 280 may perform various functions for wireless device 110. For example, data processor/controller 280 may perform processing for data received via receivers 230a to 230k and 231a to 231m and data to be transmitted via transmitters 250a to 250k and 251a to 251m. Data processor/controller 280 may control the operation of the various circuits within transceivers 220 and 222. A memory 282 may store program code and data for data processor/controller 280. Data processor/controller 280 may be implemented on one or more application specific integrated circuits (ASICs) and/or other ICs.

Wireless device 110 may support multiple band groups, multiple radio technologies, and/or multiple antennas. Wireless device 110 may include a number of LNAs to support reception via the multiple band groups, multiple radio technologies, and/or multiple antennas. Exemplary embodiments of components that may be used in the wireless device 110 are described in further detail with respect to FIGS. 3-7.

FIG. 3 illustrates an exemplary embodiment 300 of the LNA 240a of FIG. 2. The inductor device 205 includes a first inductor 304 coupled to a second inductor 306. A first transistor 312 and a second transistor 314 are coupled to the inductor device 205. A first plurality of cascode transistors 380 is coupled to the first transistor 312. A second plurality of cascode transistor 382 is coupled to the second transistor 314. For example, the first plurality of cascode transistors 380 includes a first cascode transistor 322, and the second plurality of cascode transistor 382 includes a second cascode transistor 324. The second plurality of cascode transistor 382 also includes a third cascode transistor 342 (e.g., a “divert” cascode transistor) coupled to the output 206 of the first cascode transistor 322, and the first plurality of cascode transistors 380 includes a fourth cascode transistor 344 (e.g., a “divert” cascode transistor) coupled to the output 208 of the second cascode transistor 324.

An input 330 is coupled (e.g., connected) to a gate 313 (referred to herein as a “first gate”) of the first transistor 312 and to a gate 315 (referred to herein as a “second gate”) of the second transistor 314. Although the gate 313 is referred to as a “first gate of the first transistor 312” and the gate 315 is referred to as a “second gate of the second transistor 314,” such naming convention does not require or limit either of the transistors 312, 314 to be a multi-gate device. In some embodiments, the first transistor 312 and the second transistor 314 are single-gate devices.

The first inductor 304 is coupled the first transistor 312 and coupled (e.g., connected) to ground 308. The first inductor 304 provides a degeneration inductance that enhances a transconductance of the first transistor 312. The second inductor 306 is coupled the second transistor 314 and is coupled (e.g., connected) to ground 308. The second inductor 306 provides a degeneration inductance that enhances a transconductance of the second transistor 314. Current through the first inductor 304 or the second inductor 306 causes the first inductor 304 to be magnetically coupled to the second inductor 306 according to a coupling coefficient “k”. The coupling coefficient may be less than zero and greater than negative one, resulting in a negative mutual inductance “M” 305 (e.g., a winding direction of the first inductor 304 is opposite to a winding direction of the second inductor 306). The first inductor 304 and the second inductor 306 may each have an inductance “L” such that the mutual inductance M=kL. (An inductor “dot” convention is used in the figures to indicate a relative polarity of inductor coils.)

A control circuit 390 may be coupled to provide a first control signal (Vctrl1) to a first control input of the first cascode transistor 322, a second control signal (Vctrl2) to a second control input of the second cascode transistor 324, a third control signal (Vctrl3) to a third control input of the third cascode transistor 342, and a fourth control signal (Vctrl4) to a fourth control input of the fourth cascode transistor 344, such as via multiple control lines or a bus 391. The control circuit 390 may be configured to set the control inputs to generate an amplified signal at the first output 206, at the second output 208, or at both the first output 206 and the second output 208 In an exemplary multi-output configuration of the LNA 240a, the control circuit 390 may be configured to activate (e.g., enable current to flow through) the first cascode transistor 322 and the second cascode transistor 324 and to deactivate (e.g., prevent (or reduce) current from flowing through) the third cascode transistor 342 and the fourth cascode transistor 344. The first transistor 312 amplifies an input signal 290 received at the input 330 to generate a first amplified signal at the first output 206. The second transistor 314 amplifies the input signal 290 received at the input 330 to generate a second amplified signal at the second output 208.

Alternatively or in addition to the multi-output configuration, in a first single-output configuration of the LNA 240a the control circuit 390 may be configured to activate the first cascode transistor 322 and the third cascode transistor 342 and to deactivate the second cascode transistor 324 and the fourth cascode transistor 344. The first transistor 312 and the second transistor 314 may be configured to amplify the input signal 290 (e.g., an RF input signal, “RFin”) and generate a combined amplified signal at the output 206 in the first single-output configuration.

Alternatively or in addition to the first single-output configuration, in a second single-output configuration of the LNA 240a, the control circuit 390 may be configured to activate the second cascode transistor 324 and the fourth cascode transistor 344 and to deactivate the first cascode transistor 322 and the third cascode transistor 342. The first transistor 312 and the second transistor 314 may be configured to amplify the input signal 290 (e.g., an RF input signal, “RFin”) and generate a combined amplified signal at the output 208 in the second single-output mode.

The first impedance matching circuit 352 is responsive to an amplified signal at the first output 206. For example, the first impedance matching circuit 352 may generate a first output signal 362 (e.g., a first RF output signal, “RFout1”) based on an amplified signal at the first output 206. The second impedance matching circuit 354 is responsive to an amplified signal at the second output 208. For example, the second impedance matching circuit 354 may generate a second output signal 364 (e.g., a second RF output signal, “RFout2”) based on an amplified signal at the second output 208. The impedance matching circuits 352, 354 may be implemented using various topologies and may include one or more components (reactive, resistive, or any combination thereof) in a shunt, series, or other configuration. As non-limiting examples, the impedance matching circuits 352, 354 may include an L-network topology (e.g., including series inductance (L) and shunt capacitance (C), series C and shunt L, series C and shunt C, series L and shunt L, or any combination thereof), a T-network topology, a Pi-network topology, one or more other topologies, or any combination thereof.

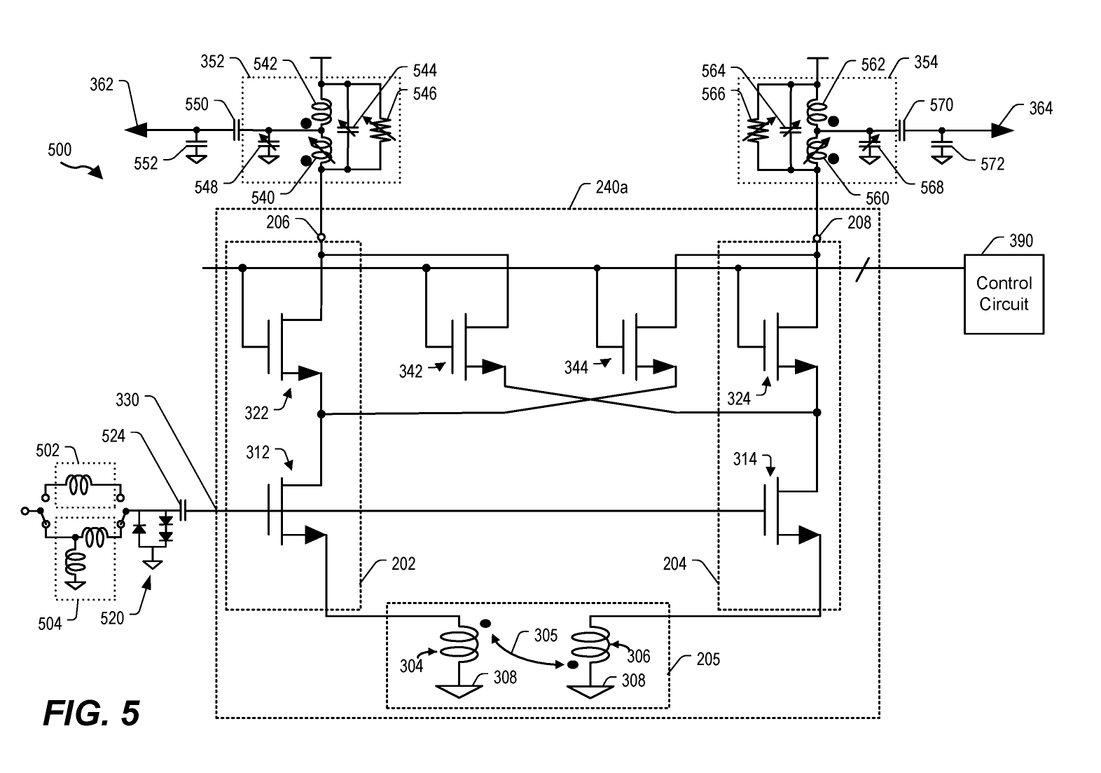

During operation, the input RF signal 290 may be received via a matching network coupled to the input 330. The first impedance matching circuit 352 may be tuned to a first frequency (e.g., a frequency of a first component carrier of the input RF signal 290) and the second impedance matching circuit 354 may be tuned to a second frequency (e.g., a frequency of a second component carrier of the input RF signal 290). Examples of a matching network and of tuning the impedance matching circuits 352 and 354 are described with reference to FIG. 5.

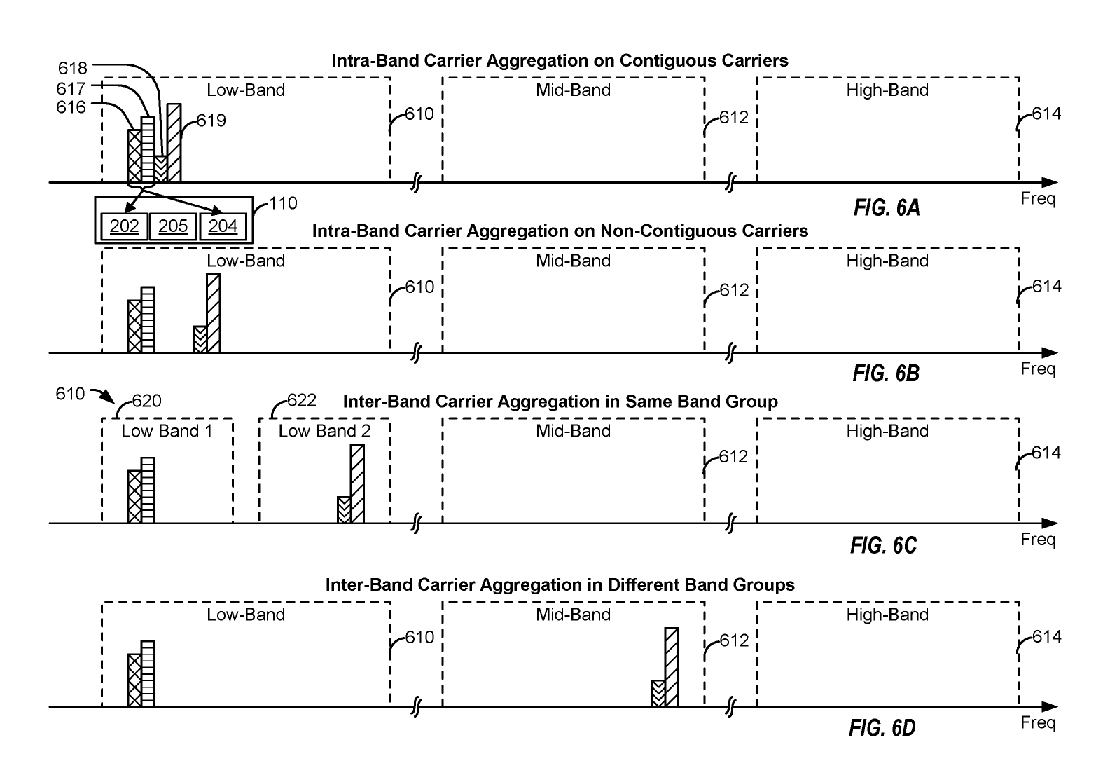

A mode of operation of the LNA 240a may be selected based on a type of carrier aggregation of the input RF signal 290. Carrier aggregation (CA) may be categorized into two types: intra-band CA and inter-band CA. Intra-band CA refers to operation on multiple carriers within the same band. Inter-band CA refers to operation on multiple carriers in different bands. Examples of intra-band CA and inter-band CA are described with reference to FIGS. 6A-6D.

In a first mode of operation (e.g., an inter-band CA mode that uses a single-output configuration of the LNA 240a) in which the input RF signal 290 does not include an intra-band CA signal, the first cascode transistor 322 and the third cascode transistor 342 may be activated, and the second cascode transistor 324 and the fourth cascode transistor 344 may be deactivated. As a result, a first output signal 392 of the first transistor 312 and a second output signal 396 of the second transistor 314 are combined and routed to the first impedance matching circuit 352. An amplified signal (based on amplifying the combined signal) may be generated at the first RF output 362 that is coupled to the first impedance matching circuit 352. Alternatively, the first cascode transistor 322 and the third cascode transistor 342 may be deactivated, and the second cascode transistor 324 and the fourth cascode transistor 344 may be activated so that a first output signal 398 of the first transistor 312 and a second output signal 394 of the second transistor 314 are combined and routed to the second impedance matching circuit 354. An amplified signal (based on amplifying the combined signal) may be generated at the second RF output 364 that is coupled to the second impedance matching circuit 354.

In the first mode of operation, the LNA 240a can be configured dynamically to provide an output signal to the first output 206 or the second output 208 under different scenarios. One or more criteria may be used to select the first output 206 or the second output 208 in the inter-band CA mode, such as receiver signal path performance (including noise figure and linearity), power consumption due to differing voltage controlled oscillator (VCO)/LO frequency planning following the output 206 or 208, or receiver de-sense performance due to different spurious emissions or “spurs” with the inter-band CA frequency combination.

In a second mode of operation (e.g., an intra-band CA mode that uses the multi-output configuration of the LNA 240a) in which the input RF signal 290 includes an intra-band CA signal, the first cascode transistor 322 and the second cascode transistor 324 may be activated, and the third cascode transistor 342 and the fourth cascode transistor 344 may be deactivated. Alternatively, the third cascode transistor 342 and the fourth cascode transistor 344 may be activated, while the first cascode transistor 322 and the second cascode transistor 324 may be deactivated in this mode, depending on de-sense performance of the receiver due to different spurious emissions or “spurs” with the inter-band CA frequency combination. The four cascode transistors, 322, 324, 342, 344 are not activated simultaneously, so “optimized” noise figure and isolation performance may be obtained. The first output signal 392 of the first transistor 312 may be routed to the first impedance matching circuit 352, and a first amplified signal corresponding to a first component carrier may be generated at the first RF output 362. The second output signal 394 of the second transistor 314 may be routed to the second impedance matching circuit 354, and a second amplified signal corresponding to a second component carrier may be generated at the second RF output 364. Although the second mode of operation using a SIMO configuration is described as corresponding to intra-band CA mode, the second mode of operation may additionally or alternatively be used with inter-band CA. For example, an LNA (e.g., a wideband LNA) may receive an input signal that spans multiple bands, such as at least a portion of a low-band that includes a first one or more carriers and at least another portion of a mid-band that includes a second one or more carriers. The second mode of operation having the SIMO configuration may be used to output the amplified first one or more carriers separately from the amplified second one or more carriers of the inter-band CA.

The mutually-coupled inductors 304 and 306 enable noise performance of the LNA 240a to be improved in the second mode of operation as compared to independent (non-coupled) degeneration inductors. Because the inductor 304 is inductively coupled to the inductor 306, a noise signal at the source one of the transistors 312, 314 induces a noise signal at the source of the other of the transistors 312, 314 via the mutual inductance. The inductor 304 is capacitively coupled to the gate 313 via gate-to-source capacitance of the first transistor 312 and the inductor 306 is capacitively coupled to the gate 315 via gate-to-source capacitance of the second transistor 314, so each of the noise signal and the induced noise signal contributes a respective noise component to the coupled gates 313, 315. Due to the negative coupling of the inductors 304, 306, the noise signal and the induced noise signal have opposite polarities, causing the noise components to the gates 313, 315 to at least partially cancel each other. This cancellation reduces the resultant noise at the output of the transistor having the noise signal at its source.

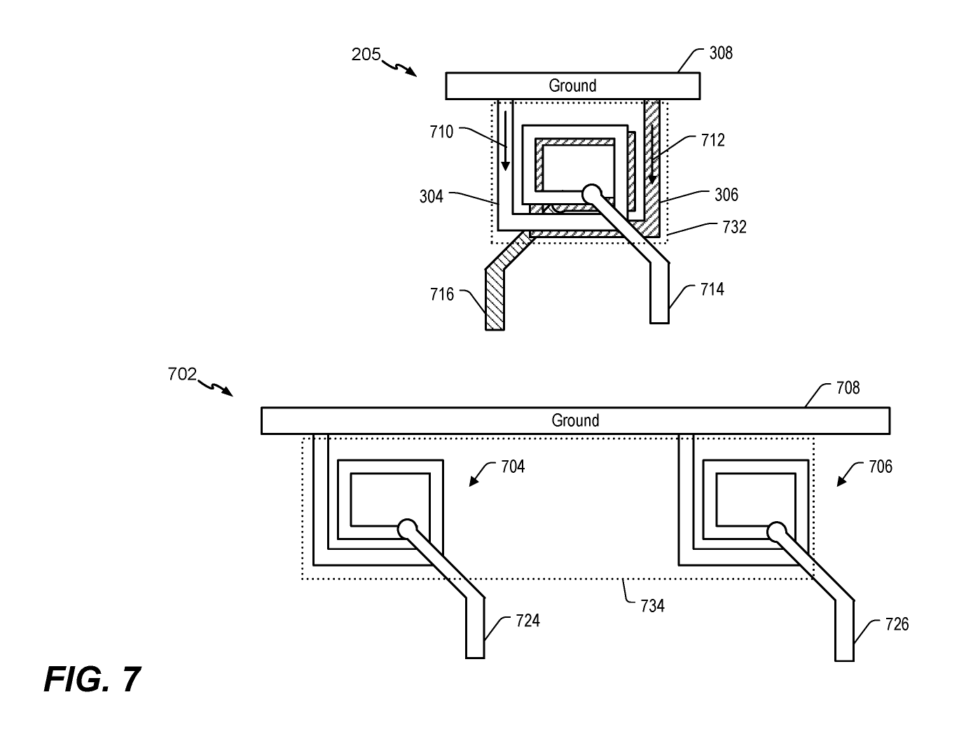

Because of the negative mutual inductance of the first inductor 304 and the second inductor 306, the LNA 240a may have an enhanced noise figure due to noise cancellation. The LNA 240 may also have a smaller area as compared to LNA architectures with degeneration inductors that are not negatively mutually coupled to each other, such as described with reference to FIG. 7.

Although FIG. 3 illustrates an exemplary implementation of the LNA 240a having the first amplifier circuit 202 coupled to the first impedance matching circuit 352 via the first output 206, the second amplifier circuit 204 coupled to the second impedance matching circuit 354 via the second output 208, and the third cascode transistor 342 and the fourth cascode transistor 344 responsive to the control circuit 390, in other implementations one or more components of the LNA 240a may be omitted. For example, the third cascode transistor 342 or the fourth cascode transistor 344 may be omitted while continuing to provide SISO and SIMO functionality.

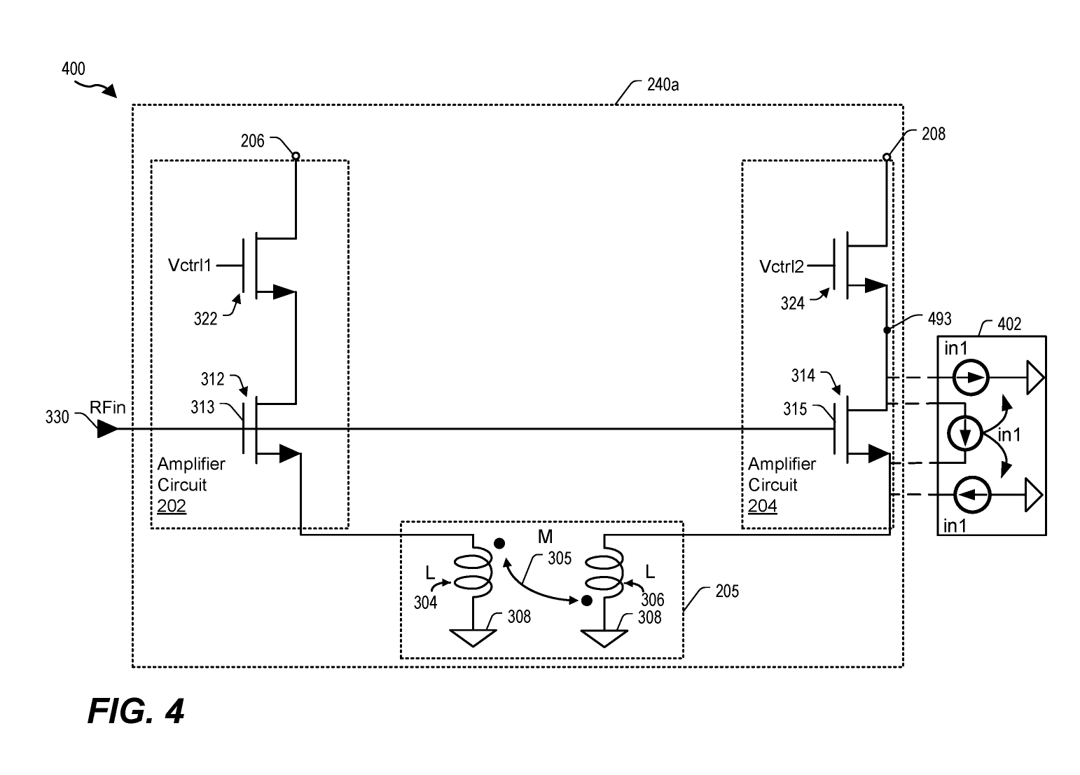

As another example, FIG. 4 illustrates a second exemplary embodiment 400 of the LNA 240a that supports intra-band CA and that includes the inductor device 205, the first transistor 312, the second transistor 314, the first cascode transistor 322, and the second cascode transistor 324 of FIG. 3. The first transistor 312 and the first cascode transistor 322 generate a first single-ended output signal at the first output 206. The second transistor 314 and the second cascode transistor 324 generate a second single-ended output signal at the second output 208.

The first output 206 and the second output 208 may be coupled to load circuits, such as the first impedance matching circuit 352 and the second impedance matching circuit 354, respectively, of FIG. 3. Illustrative examples of impedance matching circuitry are depicted in FIG. 5.

Noise performance of the circuit of FIG. 3, the circuit of FIG. 4, or both, may be modeled by determining a device output drain noise current io1 at a node 493 of the circuit of FIG. 4 that results from injecting a noise current in1 at the source of the second transistor 314 and extracting the noise current in1 from the drain of the second transistor 314. Equivalently, as illustrated with noise performance modelling components 402 that may be added to a model of the LNA 240a (via modelled electrical connections depicted as dashed lines), noise current modeling may be transformed to ground reference, more specifically, from a noise current in1 from the drain to source, to a noise current in1 at the source of the second transistor, flowing from ground to the source, and another noise current in1 at the drain of the second transistor, flowing from ground to the source. Using the ground-referred noise current transformation and mathematical derivation, the noise current io1 at the drain output can be derived with the noise current of the transistors 312 and 314, as well as characteristics of the transformer formed by the inductors 304, 306.

Using the circuit depicted in FIG. 4 with the LNA 240a coupled to the noise performance modelling components 402, and assuming both branches of the LNA 240a are identical, with finite coupling between the inductors 304, 306, the device output drain noise current io1 at the node 493 may be approximated as shown in Equation 1.

$$io 1 = - \frac{3}{4} in 1 \frac{1 + \frac{2}{3} SCR \frac{1 - k}{1 + k}}{1 + 2 SCR \frac{1 - k}{1 + k}} \qquad ( Equation 1 )$$

In Equation 1, S represents a complex frequency (e.g., from a Laplace transform of a time domain expression of in1), C represents a gate-to-source capacitance of the first transistor 312 (e.g., Cgs1) and of the second transistor 314 (e.g., Cgs2) under the simplifying assumption that C=Cgs1=Cgs2, R represents an equivalent series resistance of an input matching circuit coupled to the RF input 330 (such as depicted in FIG. 5), and k is the coupling coefficient of the first inductor 304 and the second inductor 306. As used in Equation 1, k=M/L, where M is the mutual inductance of the first inductor 304 and the second inductor 306 and L is the inductance of the first inductor 304 (e.g., L1) and of the second inductor 306 (e.g., L2) under the simplifying assumption that L=L1=L2.

Under steady state conditions where transients have settled and using S=jω, where S is the complex frequency, ω is the real frequency, and j represents a square root of −1, the magnitude of io1 can be evaluated as:

$$\begin{matrix}\vert io 1 \vert = \frac{3}{4} in 1 β \\ where & ( Equation 2 ) \\ β = \sqrt{\frac{1 + \frac{4}{9} {( ω RC α )}^{2}}{1 + 4 {( ω RC α )}^{2}}} \\ and & ( Equation 3 ) \\ α = \frac{1 - k}{1 + k} . & ( Equation 4 )\end{matrix}$$

For example, if k=0 (e.g., no coupling between the inductors 304 and 306), |io1| may have a value of 0.62in1. If k=−0.5 (e.g., moderate negative coupling between the inductors 304 and 306), |io1| may have a value of 0.46in1. If k=−1 (e.g., strong negative coupling between the inductors 304 and 306), |io1| may have a value of 0.251n1. The reduction in |io1| resulting from strong negative coupling between the inductors 304 and 306 is indicative of noise reduction in terms of device noise contribution, which may be a largest noise contribution for the LNA 240a. The reduction of device noise improves the noise figure for the LNA 240a.

FIG. 5 illustrates a third exemplary embodiment 500 of the LNA 240a that supports intra-band CA and that includes the inductor device 205, the first transistor 312, the second transistor 314, the first cascode transistor 322, and the second cascode transistor 324, the third cascode transistor 342, and the fourth cascode transistor 344 of FIG. 3. An input matching circuit coupled to the RF input 330 includes a first impedance circuit 502 that has a single inductor and a second impedance circuit 504 that has two inductors. The input matching circuit may be coupled to the RF input 330 via a coupling capacitor 524. An electrostatic discharge (ESD) device 520, such as a diode network (as illustrated), a capacitor, or another ESD device, provides an electrostatic discharge path from the input matching circuit and the RF input 330 to ground. The input matching circuit may include a set of switches configured to select the first impedance circuit 502 when an input RF signal (e.g., the input RF signal 290 of FIG. 2) corresponds to a low-band or a mid-band signal, and to select the second impedance circuit 504 when the input RF signal corresponds to a high-band signal. Examples of low-band, mid-band, and high-band signals are described in further detail with respect to FIGS. 6A-6D.

The first impedance matching circuit 352 includes multiple impedance elements coupled in parallel between the first output 206 and a voltage supply node, such as a first inductor 540 serially coupled to a second inductor 542, a capacitor 544, and a resistor 546. The first impedance matching circuit 352 also includes a capacitor 548. A first terminal of the capacitor 548 is coupled between the first inductor 540 and the second inductor 542, and a second terminal of the capacitor 548 is coupled to ground. The RF output 362 is coupled to the first impedance matching circuit 352 via a coupling capacitor 550 and a filter capacitor 552. One or more (or all) of the first inductor 540, the second inductor 542, the capacitor 544, the resistor 546, and the capacitor 548 may be adjustable (e.g., have a variable impedance) to tune the impedance of the first impedance matching circuit 352. For example, the impedance of the first impedance matching circuit 352 may be adjusted (e.g., using stored impedance control values that are calibrated to correspond to particular frequencies) to select a frequency of a first component of the RF signal received at the input 330.

The second impedance matching circuit 354 includes multiple impedance elements coupled in parallel between the second output 208 and a voltage supply node, such as a first inductor 560 serially coupled to a second inductor 562, a capacitor 564, and a resistor 566. The second impedance matching circuit 354 also includes a capacitor 568. A first terminal of the capacitor 568 is coupled between the first inductor 560 and the second inductor 562, and a second terminal of the capacitor 568 is coupled to ground. The RF output 364 is coupled to the second impedance matching circuit 354 via a coupling capacitor 570 and a filter capacitor 572. One or more (or all) of the first inductor 560, the second inductor 562, the capacitor 564, the resistor 566, and the capacitor 568 may be a variable impedance element that may be adjusted to tune an impedance of the second impedance matching circuit 354. For example, the impedance of the second impedance matching circuit 354 may be adjusted (e.g., using stored impedance control values that are calibrated to correspond to particular frequencies) to select a frequency of a second component of the RF signal received at the input 330.

The first impedance circuit 502 may be selected when a received RF signal corresponds to a low-band group signal that includes two carrier signals. The first impedance matching circuit 352 may be tuned to a frequency of one of the two carrier signals of the low-band group and the second impedance matching circuit 354 may be tuned to a frequency of the other of the two carrier signals of the low-band group in an intra-band carrier aggregation implementation.

Although FIG. 5 depicts example configurations for the impedance matching circuit 352 and the impedance matching circuit 354, in other implementations the impedance matching circuit 352, the impedance matching circuit 354, or both, may have a different topology. As previously explained, the impedance matching circuits 352, 354 may be implemented using various topologies and may include one or more components (reactive, resistive, or any combination thereof) in a shunt, series, or other configuration. As non-limiting examples, the impedance matching circuits 352, 354 may include an L-network topology (e.g., including series inductance (L) and shunt capacitance (C), series C and shunt L, series C and shunt C, series L and shunt L, or any combination thereof), a T-network topology, a Pi-network topology, one or more other topologies, or any combination thereof.

FIG. 6A is a graphical diagram showing a low-band group 610, a mid-band group 612, a high-band group 614, and an example of contiguous intra-band carrier-aggregation (CA). In the example shown in FIG. 6A, wireless device 110 is configured with four contiguous carriers 616-619 aggregated in low-band. Wireless device 110 may send and/or receive transmissions on the four contiguous carriers 616-619 within the same band group. The wireless device 110 may include an LNA (e.g., the LNA 240a of FIG. 2) that includes the first amplifier circuit 202, the second amplifier circuit 204, and the inductor device 205. The LNA may amplify a first portion of a received signal, the first portion corresponding to the first carrier 616, concurrently with amplifying a second portion of the received signal, the second portion corresponding to the second carrier 617. Although amplification of the first carrier 616 and the second carrier 617 is described as an illustrative example, the LNA may amplify any two of the carriers 616-619.

FIG. 6B is a graphical diagram showing an example of non-contiguous intra-band CA. In the example shown in FIG. 6B, wireless device 110 is configured to send and/or receive wireless communications using four non-contiguous carriers in one band in the low-band group 610. The carriers may be separated by 5 MHz, 10 MHz, or some other amount. Wireless device 110 may send and/or receive transmissions on the four non-contiguous carriers within the same band. For example, the wireless device 110 may configure an LNA (e.g., the LNA 240a) to operate in the intra-CA mode to amplify two of the carriers within the low-band group 610.

FIG. 6C is a graphical diagram showing an example of inter-band CA in the same band group. In the example shown in FIG. 6C, wireless device 110 is configured to send and/or receive wireless communications using four carriers in two bands 620, 622 in the low-band group 610. Wireless device 110 may send and/or receive transmissions on the four carriers in different bands in the same band group. For example, the wireless device 110 may configure an LNA (e.g., the LNA 240a) to operate in the inter-CA mode to amplify a carrier within the band 620 or the band 622.

FIG. 6D is a graphical diagram showing an example of inter-band CA in different band groups. In the example shown in FIG. 6D, wireless device 110 is configured to send and/or receive wireless communications using four carriers in two bands in different band groups, which include two carriers in one band in the low-band group 610 and two carriers in another band in the mid-band group 612. Wireless device 110 may send and/or receive transmissions on the four carriers in different bands in different band groups. For example, the wireless device 110 may configure an LNA (e.g., the LNA 240a) to operate in the inter-CA mode to amplify a carrier within the low-band group 610 or the mid-band group 612.

FIGS. 6A to 6D show four examples of carrier aggregation. Carrier aggregation may also be supported for other combinations of bands and band groups.

FIG. 7 depicts an exemplary embodiment of the inductor device 205 and an example of a pair of independent inductors 702. The pair of independent inductors 702 includes a first inductor 704 coupled to a first port 724 and to a ground line 708. The pair of independent inductors 702 includes a second inductor 706 coupled to a second port 726 and to the ground line 708. An area 734 includes an area of the first inductor 704, an area of the second inductor 706, and an area between the inductors 704, 706. For example, spacing apart the inductors 704, 706 reduces the magnetic coupling between the inductors 704, 706.

In contrast to the spaced-apart inductors 704 and 706, the inductor device 205 includes the first inductor 304 and the second inductor 306 in an overlapping, counter-wound configuration. The first inductor 304 provides a first current path 710 between the ground 308 and a first port 714. The second inductor 306 provides a second current path 712 between the ground 308 and a second port 716. One or more windings of the first inductor 304 is aligned with and above (e.g., in a higher metal layer than) one or more windings of the second inductor 306 for increased magnetic coupling between the first inductor 304 and the second inductor 306. An area 732 of the inductor device 205 may be approximately equal to the area of the first inductor 304 and is therefore smaller than the area 734 of the pair of independent inductors 702.

Although FIG. 7 depicts each of the inductors 304, 306 as having a single winding, it should be understood that the inductors 304, 306 may have any number of windings. For example, the windings may be formed in a separate metal layers and interconnected with conductive vias. Windings of the inductor 304 may be stacked above, stacked below, or interleaved among windings of the inductor 306. By overlapping the inductors 304 and 306, magnetic coupling between the inductors 304 and 306 is increased and a footprint of the device 205 is decreased as compared to the pair of independent inductors 702.

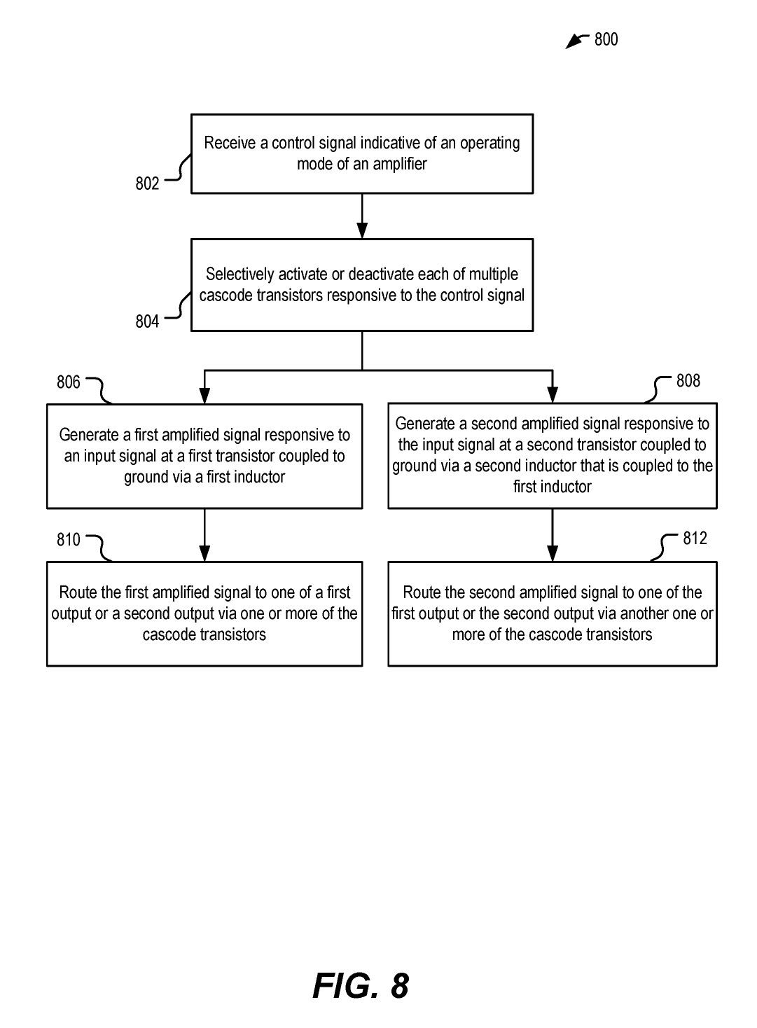

Referring to FIG. 8, an exemplary embodiment of a method is depicted and generally designated 800. The method 800 may be performed in a wireless device that includes an amplifier with an inductor device having a first inductor connected to ground and having a second inductor connected to ground and coupled to the first inductor. For example, the method 800 may be performed by the wireless device 110 of FIG. 1 that includes the LNA 240a of FIGS. 2-5. To illustrate, the method 800 may be performed by the LNA 240a of FIG. 3.

The method 800 may include receiving a control signal indicative of an operating mode of an amplifier, at 802. For example, the control signal may be received from the control circuit 390 via the multiple control lines or bus 391 of FIG. 5. The control signal may indicate whether the amplifier is to operate in a first mode (e.g., a SISO mode) or a second mode (e.g., a SIMO mode).

The method 800 may include selectively activating or deactivating each of multiple cascode transistors responsive to the control signal. For example, when the control signal indicates the amplifier is to operate in a SISO mode, the cascode transistors 322 and 342 of FIG. 3 may be activated to couple the amplifier transistors 312, 314 to the output 206, and the cascode transistors 324 and 344 may be deactivated. As another example, when the control signal indicates the amplifier is to operate in a SISO mode, the cascode transistors 322 and 342 of FIG. 3 may be deactivated, and the cascode transistors 324 and 344 may be activated to couple the amplifier transistors 312, 314 to the output 208. As a third example, when the control signal indicates the amplifier is to operate in a SIMO mode, the cascode transistors 322 and 324 of FIG. 3 may be activated, and the divert cascode transistors 342 and 344 may be deactivated.

The method 800 includes generating a first amplified signal responsive to an input signal at a first transistor that is coupled to ground via a first inductor, at 806, and generating a second amplified signal responsive to the input signal at a second transistor coupled to ground via a second inductor that is coupled to the first inductor, at 808. For example, the first inductor and the second inductor may correspond to the first inductor 304 and the second inductor 306 of the inductor device 205 of FIG. 3.

The first amplified signal may be routed to one of a first output or a second output via one or more of the cascode transistors, at 810. For example, when the cascode transistor 322 is activated, the amplified signal generated by the first amplifier transistor 312 of FIG. 3 may be routed to the output 206, and when the divert transistor 344 is activated, the amplified signal generated by the first amplifier transistor 312 may be routed to the output 208. The second amplified signal may be routed to one of the first output or the second output via another one or more of the cascode transistors, at 812. For example, when the cascode transistor 324 is activated, the amplified signal generated by the second amplifier transistor 314 of FIG. 3 may be routed to the output 208, and when the divert transistor 342 is activated, the amplified signal generated by the second amplifier transistor 314 may be routed to the output 206.

Although FIG. 8 depicts a particular order of elements of the method 800, it should be understood that, in other embodiments, elements of the method 800 may be performed in another order. In addition, multiple elements of the method 800 may be performed simultaneously or substantially simultaneously. For example, the first amplified signal may be generated (at 806) simultaneously with (or substantially simultaneously with) being the second amplified signal being generated (at 808).

The method 800 enables generation of multiple output signals based on a common input signal using degeneration inductors having smaller area as compared to using degeneration inductors that are not mutually coupled. In addition, the transconductance of the first transistor and the second transistor may be increased, and the noise figure may be reduced as compared to amplifiers having degeneration inductors that are not mutually coupled.

In accordance with the above-described implementations, an apparatus includes means for providing a first inductance, the means for providing the first inductance connected to ground. For example, the means for providing the first inductance may include the first inductor 304 of FIGS. 3-5 or FIG. 7, one or more other inductors or other circuits configured to provide an inductance, or any combination thereof.

The apparatus may include means for providing a second inductance, the means for providing the second inductance connected to ground and coupled to the means for providing the first inductance. For example, the means for providing a second inductance may include the second inductor 306 of FIGS. 3-5 or FIG. 7, one or more other inductors or other circuits configured to provide an inductance, or any combination thereof.

The apparatus may include means for generating a first amplified signal responsive to an input signal, the means for generating the first amplified signal coupled to the means for providing the first inductance. For example, the means for generating a first amplified signal may include the first transistor 312 of FIGS. 3-5, one or more other transistors, transconductance devices, amplifiers, or other circuits configured to generate an amplified signal, or any combination thereof.

The apparatus may include means for generating a second amplified signal responsive to the input signal, the means for generating the second amplified signal coupled to the means for providing the second inductance. For example, the means for generating a second amplified signal may include the second transistor 314 of FIGS. 3-5, one or more other transistors, transconductance devices, amplifiers, or other circuits configured to generate an amplified signal, or any combination thereof.

The apparatus may include means for switching coupled to the means for generating the first amplified signal and coupled to a first output. For example, the first means for switching may include the first cascode transistor 322 of FIGS. 3-5, one or more other transistors, switches, other circuits configured to selectively couple or decouple, or any combination thereof.

The apparatus may include a second means for switching coupled to the means for generating the second amplified signal and coupled to a second output. For example, the second means for switching may include the second cascode transistor 324 of FIGS. 3-5, one or more other transistors, switches, other circuits configured to selectively couple or decouple, or any combination thereof.

The means for generating the first amplified signal may include a means for gating, and the means for generating the second amplified signal may include a means for gating that is coupled to the means for gating of the means for generating the first amplified signal. For example, the means for gating of the means for generating the first amplified signal may include the gate 313 of FIG. 3, one or more other switching control inputs or other circuits configured to activate or deactivate a switch, or any combination thereof. The means for gating of the means for generating the second amplified signal may include the gate 315 of FIG. 3, one or more other switching control inputs or other circuits configured to activate or deactivate a switch, or any combination thereof.

The first output may be coupled to a first means for impedance matching and the second output may be coupled to a second means for impedance matching. For example, the first means for impedance matching may include the first impedance matching circuit 352 of FIG. 3 or FIG. 5, one or more other impedance matching component or other circuits configured to impedance match, or any combination thereof. The second means for impedance matching may include the second impedance matching circuit 354 of FIG. 3 or FIG. 5, one or more other impedance matching component or other circuits configured to impedance match, or any combination thereof.

Those of skill in the art would understand that information and signals may be represented using any of a variety of different technologies and techniques. For example, data, instructions, commands, information, signals, bits, symbols, and circuits that may be referenced throughout the above description may be represented by voltages, currents, electromagnetic waves, magnetic fields or particles, optical fields or particles, or any combination thereof.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
an inductor device including a first inductor coupled to a second inductor, the first inductor and the second inductor connected to ground;
a first transistor coupled to the inductor device;
a second transistor coupled to the inductor device;
a first cascode transistor coupled to the first transistor, the first cascode transistor coupled to a first output; and
a second cascode transistor coupled to the second transistor, the second cascode transistor coupled to a second output.

2. The apparatus of claim 1, the first inductor coupled to the second inductor according to a coupling coefficient.

3. The apparatus of claim 2, wherein the coupling coefficient is less than zero and greater than negative one.

4. The apparatus of claim 1, the first transistor comprising a first gate that is coupled to a second gate of the second transistor.

5. The apparatus of claim 1, further comprising a third cascode transistor coupled to the second transistor, the third cascode transistor coupled to the first output.

6. The apparatus of claim 5, further comprising a fourth cascode transistor coupled to the first transistor, the fourth cascode transistor coupled to the second output.

7. The apparatus of claim 1, the first output comprising a first single-ended output and the second output comprising a second single-ended output.

8. The apparatus of claim 1, the first cascode transistor coupled to a first impedance matching circuit and the second cascode transistor coupled to a second impedance matching circuit.

9. The apparatus of claim 1, wherein in a first mode of operation, a first output signal of the first transistor and a second output signal of the second transistor are combined and routed to a first impedance matching circuit, and wherein in a second mode of operation, the first output signal is routed to the first impedance matching circuit and the second output signal is routed to a second impedance matching circuit.

10. The apparatus of claim 9, wherein the first mode of operation corresponds to an inter-band carrier aggregation mode and wherein the second mode of operation corresponds to an intra-band carrier aggregation mode.

11. The apparatus of claim 9, wherein the first mode of operation corresponds to a single-input single-output low noise amplifier (LNA) mode and wherein the second mode of operation corresponds to a single-input multiple-output LNA mode.

12. An apparatus comprising:
means for providing a first inductance, the means for providing the first inductance connected to ground;
means for providing a second inductance, the means for providing the second inductance connected to ground and coupled to the means for providing the first inductance;
means for generating a first amplified signal responsive to an input signal, the means for generating the first amplified signal coupled to the means for providing the first inductance;
means for generating a second amplified signal responsive to the input signal, the means for generating the second amplified signal coupled to the means for providing the second inductance;
first means for switching coupled to the means for generating the first amplified signal and coupled to a first output; and
second means for switching coupled to the means for generating the second amplified signal and coupled to a second output.

13. The apparatus of claim 12, wherein the means for providing the first inductance is coupled to the means for providing the second inductance according to a coupling coefficient.

14. The apparatus of claim 13, wherein the coupling coefficient is less than zero and greater than negative one.

15. The apparatus of claim 12, the means for generating the first amplified signal comprising a means for gating, and the means for generating the second amplified signal comprising a means for gating that is coupled to the means for gating of the means for generating the first amplified signal.

16. The apparatus of claim 12, the first output comprising a first single-ended output and the second output comprising a second single-ended output.

17. The apparatus of claim 12, wherein the first output is coupled to a first means for impedance matching and the second output is coupled to a second means for impedance matching.

18. The apparatus of claim 12, further comprising third means for switching coupled to the second means for generating the second amplified signal and coupled to the first output.

19. The apparatus of claim 18, further comprising fourth means for switching coupled to the first means for generating the first amplified signal and coupled to the second output.

20. The apparatus of claim 12, wherein in a first mode of operation, the first amplified signal and the second amplified signal are combined and routed to a first means for impedance matching, and wherein in a second mode of operation, the first amplified signal is routed to the first means for impedance matching and the second amplified signal is routed to a second means for impedance matching.
